(19) United States
(12) Patent Application Publication
(10) Pub. No.: US 2009/0206317 A1
(43) Pub. Date: Aug. 20, 2009

(54) PHASE CHANGE MEMORY DEVICE AND METHOD FOR MANUFACTURING THE SAME

(75) Inventor: Hyun-Seok Kang, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/329,054

(22) Filed: Dec. 5, 2008

(30) Foreign Application Priority Data
Feb. 15, 2008 (KR) 10-2008-0013852

(51) Int. Cl. H01L 45/00

(52) U.S. Cl. 257/4; 438/102; 257/E45.002

(57) ABSTRACT

A method for manufacturing a phase change memory device includes steps of forming a first encapsulation layer on a semiconductor substrate having a bottom electrode contact and a phase change material layer stack structure contacting the bottom electrode contact, and forming a plurality of encapsulation spacers on sidewalls of the phase change material layer stack structure using a spacer etching process.

The present application claims priority under 35 U.S.C. § 119(a) to Korean application number 10-2008-0013852, filed on Feb. 15, 2008, in the Korean Intellectual Property Office, which is incorporated herein by reference in its entirety as if set forth in full.

### BACKGROUND

1. Technical Field

The embodiments described herein relate to a memory device and a method for manufacturing the same and, more particularly, to a phase change memory device and a method for manufacturing the same.

2. Related Art

Memory devices are commonly divided into volatile random access memory (RAM) devices that lose input information when power is interrupted and a non-volatile read-only memory (ROM) devices that can continuously hold input information even when power is interrupted. Currently, dynamic RAM (DRAM) devices and static RAM (SRAM) devices are generally used as the RAM devices, and flash memory devices are used as the ROM devices.

DRAM devices have advantages in that power consumption is reduced and random access is possible. However, DRAM devices also have disadvantages in that they are volatile and require high charge storage capacity so that capacity of capacitors should be increased. The SRAM devices are commonly used as cache memory devices, and have advantages in that random access is possible and they have a high operation speed. However, SRAM devices also have disadvantages in that they are volatile and have a substantial size so that the manufacturing costs are increased. In addition, in the flash memory devices, while they are non-volatile, a high operation voltage is required when compared to a power source voltage due to the fact that two gates are stacked upon each other. Accordingly, since a separate booster circuit is needed to supply a voltage required for write and delete operations, it is difficult to accomplish a high level of integration and a high operation speed.

In order to overcome the disadvantages of these memory devices, ferroelectric random access memory (FRAM) devices, magnetic random access memory (MRAM) devices, and phase change random access memory (PRAM) devices have been developed. Among these RAM devices, the PRAM device is a memory device that reads and writes information by making use of a phase change property of a phase change material having high resistance in an amorphous phase and low resistance in a crystalline phase. The PRAM device provides advantages including high operational speeds and high integration levels when compared to the flash memory devices.

The phase change material is a material whereby phase changes occur between the crystalline phase and the amorphous phase depending upon a temperature thereof. In the crystalline phase, the phase change material has low resistance and regular atomic arrangement when compared to the amorphous phase. For example, a phase change material can include a Chalcogenide, such as a compound made of GST, that is, germanium (Ge), antimony (Sb), and tellurium (Te).

In the PRAM device, as current is applied through bottom electrodes, the temperature of a phase change material layer is changed by Joule heat generated due to the current application. Accordingly, by appropriately changing the applied current, the crystal structure of the phase change material layer can be changed between the crystalline state and the amorphous state. For example, a phase change can occur by the Joule heat between the crystalline state, i.e., a set state, having low resistance and the amorphous state, i.e., a reset state, having high resistance. In the PRAM device, during read and write modes of operation, by sensing the current flowing through a phase change layer, the device can determine whether the information stored in a phase change memory cell is a set state data (0) or a reset state data (1).

However, as the PRAM device operates repeatedly; the phase change material undergoes repeated expansion and contraction. Accordingly, the phase change material is likely to delaminate from bottom electrode contacts (BECs) due to the change in the volume thereof. Thus, after the phase change material layer and top electrodes are formed, in order to prevent the delamination of the phase change material, an encapsulation layer is formed, which will be described with reference to FIG. 1.

FIG. 1 is a cross sectional view of a conventional method for manufacturing a phase change memory device. In FIG. 1, an interlayer dielectric 101, a bottom electrode contact 103, and an insulation layer 105 are formed on a semiconductor substrate 101. A phase change material layer 107, a top electrode 109, and an etch stop layer 111 are sequentially formed such that the phase change material layer 107 contacts the bottom electrode contact 103. Then, an encapsulation layer 113 is formed on the entire structure.

The encapsulation layer 113 can be formed as a silicon nitride layer (SiN). However, since the silicon nitride layer does not have high compressive stress, the phase change material delaminates from the bottom electrode contact 103. In addition, since the encapsulation layer 113 is formed of silicon nitride at a high temperature of about 400° C., the phase change material layer 107 will be thermally influenced when forming the encapsulation layer 113. Furthermore, the silicon nitride layer cannot be sufficiently deposited along the sidewalls of the phase change material layer 107 due to its poor step coverage. Accordingly, an overhang phenomenon occurs, and the spaces between patterns of the phase change material layer 107 are not completely filled during subsequent processes for forming an interlayer dielectric. Moreover, the silicon nitride layer is deposited relatively thin on the sidewalls of the phase change material layer 107 (see the part ‘A’).

After the silicon nitride layer is formed, the interlayer dielectric is formed through a high density plasma chemical vapor deposition (HDP CVD) process to fill the spaces between the patterns of the phase change material layer 107. Accordingly, a clipping phenomenon occurs in which the silicon nitride layer is pared on the outermost line of the phase change material, i.e., within an area where the gap between a peripheral region and a cell region is substantial, due to the sputter processes of high density plasma. Thus, the phase change material is likely to be exposed.

As a result, due to the characteristics of silicon nitride being used as the encapsulation layer, it is difficult to improve the adhesion between the phase change material layer and the bottom electrode contact. In addition, complete encapsulation of the phase change material cannot be ensured, whereby the characteristics of the phase change memory device can be deteriorated and the manufacturing yield can decrease.

### SUMMARY

A phase change memory device capable of improving adhesion characteristic of a phase change material layer with respect to an underlying layer, and a method for manufacturing the same are described herein.

Another object of the present invention is to provide a phase change memory device so that a phase change material can be effectively protected from outer circumstances, and a method for manufacturing the same.

Still another object of the present invention is to provide a phase change memory device so that the reliability of subsequent processes can be secured, and a method for manufacturing the same.

In one aspect, a method for manufacturing a phase change memory device includes steps of forming a first encapsulation layer on a semiconductor substrate having a bottom electrode contact and a phase change material layer stack structure contacting the bottom electrode contact, and forming a plurality of encapsulation spacers on sidewalls of the phase change material layer stack structure using a spacer etching process.

In another aspect, a method for manufacturing a phase change memory device includes steps of forming, on a semiconductor substrate, a bottom electrode contact and a phase change material layer stack structure contacting the bottom electrode contact, and forming an amorphous carbon nonconductive thin film on the semiconductor substrate including the phase change material layer stack structure.

In another aspect, a method for manufacturing a phase change memory device includes steps of forming a first encapsulation layer on a semiconductor substrate and over a bottom electrode contact and a phase change material layer stack structure contacting the bottom electrode contact, and forming a second encapsulation layer on the first encapsulation layer and over the bottom electrode contact and phase change material layer stack structure.

In another aspect, a phase change memory device includes a bottom electrode contact, a phase change material layer stack structure contacting the bottom electrode contact, a plurality of encapsulation spacers, each formed on sidewalls of the phase change material layer stack structure, and an encapsulation layer formed on the bottom electrode contact, the phase change layer stack structure, and the plurality of encapsulation spacers.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a cross sectional view of a conventional method for manufacturing a phase change memory device;

FIGS. 2a to 2d are cross sectional views of an exemplary method for manufacturing a phase change memory device in accordance with one embodiment; and

FIG. 3 is a cross sectional view of another exemplary method for manufacturing a phase change memory device in accordance with another embodiment.

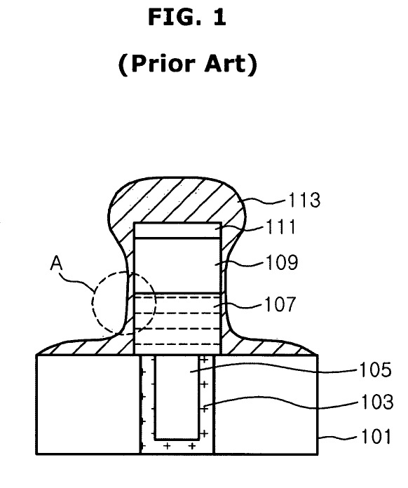

### DETAILED DESCRIPTION

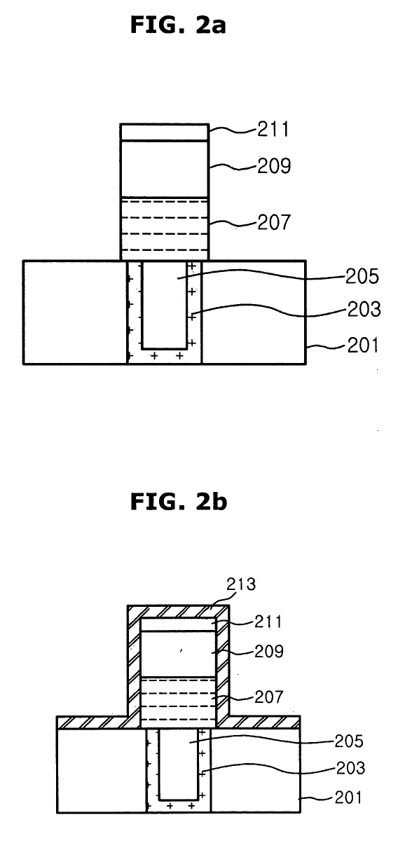

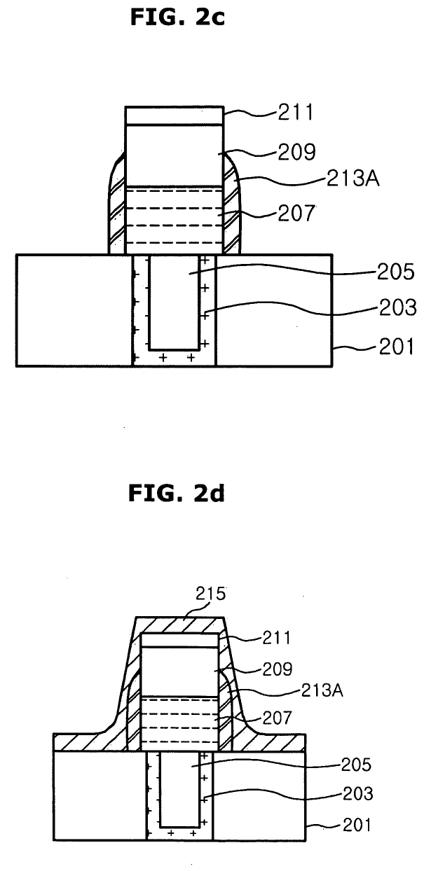

FIGS. 2a to 2d are cross sectional views of an exemplary method for manufacturing a phase change memory device in accordance with one embodiment. In FIG. 2a, an interlayer dielectric 201 can be formed on a semiconductor substrate (not shown), and predetermined portions of the interlayer dielectric 201 can be subsequently patterned. For example, a first conductive material and an insulation material can be formed along an entire structure, and then planarized to produce a bottom electrode contact 203, in which an insulation layer 205 can be filled.

Next, by sequentially depositing a phase change material, a second conductive material and an etch stop material can be formed on the resultant structure and patterning. For example, a stack structure, i.e., a phase change material layer stack structure, can include a phase change material layer 207, a top electrode 209, and an etch stop layer 211 formed on the bottom electrode contact 203.

In FIG. 2b, a first encapsulation layer 213 can be formed on the resultant structure. For example, the first encapsulation layer 213 can be formed as an amorphous thin film, such as an amorphous carbon thin film. Here, the amorphous carbon thin film can provide advantages in that it has an excellent adhesion characteristics with respect to an oxide layer and a nitride layer, as well as having high compressive stress so that it can sufficiently function as an encapsulation layer.

The amorphous carbon thin film can be deposited through plasma enhanced chemical vapor deposition (PECVD) at a temperature within a range of about 200° C. to about 400° C. In addition, acetylene (C₂H₂), helium (He), and hydrogen (H₂) gases can be used as a source gas, and plasma of within a range of about 300 W to about 500 W can be used under a pressure within a range of about 0.5 Torr to about 1.5 Torr. Accordingly, since a low temperature decomposition gas, such as acetylene or helium, can be used, the amorphous carbon thin film can be deposited at a low temperature within a range of about 200° C. to about 400° C. when compared to a silicon nitride layer. Thus, thermal influences exerted to the phase change material layer 207 can be minimized. Furthermore, since the amorphous carbon thin film can have diamond-like bond formations, the carbon thin film can exhibit nonconductive characteristics.

The amorphous carbon thin film formed in this way can have a compressive stress within a range of about 5×10E9 to about 6×10E9. Thus, even when phase changes repeatedly occur, delamination between the phase change material layer 207 and the bottom electrode contact 203 can be prevented.

In FIG. 2c, by etching the first encapsulation layer 213 through a spacer forming process, for example, encapsulation spacers 213A can be formed. By conducting a planarization etching process using oxygen plasma without conducting a masking process, portions of the amorphous carbon thin film on plane surfaces can be removed due to the directionality of the plasma. As a result, the encapsulation spacers 213A can be formed on the sidewalls of the phase change material layer stack structure 207, 209, and 211.

A height of the encapsulation spacers 213A can be controlled to cover the sidewalls of the phase change material layer 207, and to allow upper ends of the encapsulation spacers 213A to be positioned between the top electrode 209 and the etch stop layer 211. Accordingly, the sidewalls of the phase change material layer 207 can be prevented from being exposed.

In FIG. 2d, by forming a second encapsulation layer 215 on the resultant structure, the entire phase change material layer stack structure 207, 209, and 211 can be encapsulated. Here, the second encapsulation layer 215 can be formed as a silicon nitride layer at a temperature within a range of about 350° C. to about 450° C. Since the sidewalls of the phase change material layer 207 can be protected by the encapsulation spacers 213A, even when the second encapsulation layer 215 is formed at a high temperature of about 400° C., the thermal influences exerted to the phase change material layer 207 can be minimized.

Although the second encapsulation layer 215 can have relatively poor step coverage characteristics, since the sidewalls of the phase change material layer 207 can already be protected by the encapsulation spacers 213A, an overhang phenomenon does not occur. Accordingly, gap fill characteristics can be secured when subsequently forming an interlayer dielectric. Even when the subsequent interlayer dielectric forming process is conducted through HDP CVD, since the amorphous carbon thin film has a high etching selectivity, the sidewalls of the phase change material layer 207 can be stably protected by the encapsulation spacers 213A even on the outermost line of a cell region.

Alternatively, the phase change material layer of a phase change memory device can be protected by an encapsulation layer that includes an amorphous carbon nonconductive thin film. For example, the phase change material layer 207 can be protected using the first encapsulation layer 213, as shown in FIG. 2b. In order to allow the first encapsulation layer 213 to have the nonconductive characteristics, the first encapsulation layer 213 can be deposited through PECVD at a temperature within a range of about 200° C. to about 400° C. using acetylene (C₂H₂), helium (He), and hydrogen (H₂) gases, for example, as a source gas, and a plasma within a range of about 300 W to about 500 W under a pressure within a range of about 0.5 Torr to about 1.5 Torr.

Since the amorphous carbon nonconductive thin film formed in these conditions can have diamond-like bond formations, it can function as an insulation material. In addition, since the amorphous carbon nonconductive thin film can be deposited to a substantially uniform thickness, excellent gap fill characteristics can be secured when subsequently conducting processes for forming an interlayer dielectric. Furthermore, since the amorphous carbon nonconductive thin film can have a high etching selectivity to an oxide layer, when conducting the subsequent processes for forming the interlayer dielectric using an oxide through HDP CVD, it is possible to prevent a clipping phenomenon from occurring on the outermost line of a cell region.

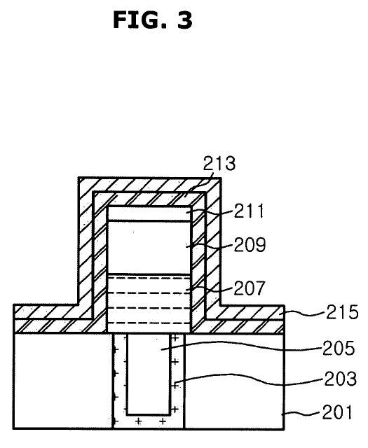

FIG. 3 is a cross sectional view of another exemplary method for manufacturing a phase change memory device in accordance with another embodiment. In FIG. 3, a phase change material layer stack structure 207, 209, and 211 can be protected by a double-layered structure of a first encapsulation layer and a second encapsulation layer. For example, a first encapsulation layer 213 and a second encapsulation layer 215 can be sequentially formed on an entire structure that is formed with the phase change material layer stack structure 207, 209, and 211.

Here, the first encapsulation layer 213 can include an amorphous carbon thin film deposited through PECVD at a temperature within a range of about 200° C to about 400° C. For example, acetylene (C₂H₂), helium (He), and hydrogen (H₂) gases can be used as a source gas, and a plasma within a range of about 300 W to about 500 W can be used under a pressure within a range of about 0.5 Torr to about 1.5 Torr. In addition, the second encapsulation layer 215 can be formed at a temperature within a range of about 350° C. to about 450° C. as a silicon nitride layer.

Since the amorphous carbon thin film can have a high compressive stress, it can sufficiently perform the function as an encapsulation layer. In addition, since the low temperature decomposition gas, such as acetylene or helium, can be used, the amorphous carbon thin film can be deposited at a low temperature within a range of about 200° C. to about 400° C., whereby the phase change material layer 207 can be protected from thermal influences.

Since a phase change material layer can be encapsulated using an amorphous carbon thin film having high compressive stress, even when phase changes repeatedly occur by the operation of a phase change memory device, the structure of the phase change memory device can be prevented from being deformed, whereby the adhesion between the phase change material layer and bottom electrode contacts can be improved.

In addition, since the amorphous carbon thin film can have excellent step coverage characteristics, the sidewalls of the phase change material layer can be protected safely from the outside influences. Moreover, since an encapsulation layer can be formed to a substantially uniform thickness on the phase change material layer, excellent gap fill characteristics can be secured when forming an interlayer dielectric during a subsequent process.

Furthermore, since the amorphous carbon thin film can have excellent etching selectivity to an oxide layer used as the encapsulation layer, when the interlayer dielectric comprising an oxide layer is deposited during a subsequent process, it is possible to prevent a clipping phenomenon from occurring on the outermost line of the phase change material layer. Accordingly, the sidewalls of the phase change material layer can be prevented from becoming exposed. Thus, encapsulation characteristics for the phase change material layer can be improved so that the thermal influences exerted upon the phase change material from the outside influences can be reduced and operational characteristics and reliability of the phase change memory device can be improved.

Since the adhesion between the bottom electrode contacts and the phase change material layer can be improved, the operational reliability of the phase change material layer can be improved. Accordingly, mis-operation of the phase change memory device can be prevented, and manufacturing yield can be increased, so that the phase change memory device can be successfully incorporated into various electronic devices.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A method for manufacturing a phase change memory device, comprising the steps of:
forming a first encapsulation layer on a semiconductor substrate having a bottom electrode contact and a phase change material layer stack structure contacting the bottom electrode contact; and
forming a plurality of encapsulation spacers on sidewalls of the phase change material layer stack structure using a spacer etching process.

2. The method according to claim 1, wherein the first encapsulation layer includes an amorphous carbon thin film.

3. The method according to claim 2, wherein the first encapsulation layer is deposited at a temperature within a range of 200° C. to 400° C.

4. The method according to claim 3, wherein the first encapsulation layer is deposited through PECVD using one of acetylene (C₂H₂), helium (He), and hydrogen (H₂) gases as a source gas.

5. The method according to claim 3, wherein the first encapsulation layer is deposited using a plasma within a range of 300 W to 500 W under a pressure within a range of 0.5 Torr to 1.5 Torr.

6. The method according to claim 1, wherein the phase change material layer stack structure includes a phase change material layer, a top electrode, and an etch stop layer.

7. The method according to claim 6, wherein the spacer etching process is conducted such that upper ends of the encapsulation spacers are positioned between the top electrode and the etch stop layer.

8. The method according to claim 7, wherein the spacer etching process includes a planarization etching process using oxygen plasma.

9. The method according to claim 1, further comprising the step of forming a second encapsulation layer on an entire structure that is formed with the encapsulation spacers.

10. The method according to claim 9, wherein the second encapsulation layer includes a silicon nitride layer.

11. The method according to claim 10, wherein the second encapsulation layer is formed at a temperature within a range of 350° C. to 450° C.

12. A method for manufacturing a phase change memory device, comprising the steps of:
forming, on a semiconductor substrate, a bottom electrode contact and a phase change material layer stack structure contacting the bottom electrode contact; and
forming an amorphous carbon nonconductive thin film on the semiconductor substrate including the phase change material layer stack structure.

13. The method according to claim 12, wherein the amorphous carbon nonconductive thin film is deposited at a temperature within a range of 200° C. to 400° C.

14. The method according to claim 13, wherein the amorphous carbon nonconductive thin film is deposited through PECVD using one of acetylene (C₂H₂), helium (He), and hydrogen (H₂) gases as a source gas.

15. The method according to claim 14, wherein the amorphous carbon nonconductive thin film is deposited using a plasma within a range of 300 W to 500 W under a pressure within a range of 0.5 Torr to 1.5 Torr.

16. A method for manufacturing a phase change memory device, comprising the steps of:
forming a first encapsulation layer on a semiconductor substrate and over a bottom electrode contact and a phase change material layer stack structure contacting the bottom electrode contact; and
forming a second encapsulation layer on the first encapsulation layer and over the bottom electrode contact and phase change material layer stack structure.

17. The method according to claim 16, wherein the first encapsulation layer includes an amorphous carbon thin film.

18. The method according to claim 17, wherein the first encapsulation layer is deposited at a temperature within a range of 200° C. to 400° C.

19. The method according to claim 18, wherein the first encapsulation layer is deposited through PECVD using one of acetylene (C₂H₂), helium (He), and hydrogen (H₂) gases as a source gas.

20. The method according to claim 18, wherein the first encapsulation layer is deposited using a plasma within a range of 300 W to 500 W under a pressure within a range of 0.5 Torr to 1.5 Torr.

21. The method according to claim 16, wherein the second encapsulation layer includes a silicon nitride layer.

22. The method according to claim 21, wherein the second encapsulation layer is formed at a temperature within a range of 350° C. to 450° C.

23. A phase change memory device, comprising:
a bottom electrode contact;
a phase change material layer stack structure contacting the bottom electrode contact;
a plurality of encapsulation spacers, each formed on sidewalls of the phase change material layer stack structure; and
an encapsulation layer formed on the bottom electrode contact, the phase change layer stack structure, and the plurality of encapsulation spacers.

24. The phase change memory device according to claim 23, wherein the plurality of encapsulation spacers include amorphous carbon thin film spacers.

25. The phase change memory device according to claim 23, wherein phase change material layer stack structure includes a phase change material layer, a top electrode, and an etch stop layer, and upper ends of the plurality of encapsulation spacers are positioned between the top electrode and the etch stop layer.

26. The phase change memory device according to claim 23, wherein the encapsulation layer includes a silicon nitride layer.
